(19) United States
(12) Patent Application Publication
(10) Pub. No.: US 2025/0261499 A1
(43) Pub. Date: Aug. 14, 2025

(54) PEROVSKITE SOLAR CELL AND PREPARATION METHOD THEREOF, AND AN ELECTRICAL APPARATUS

(71) Applicant: Contemporary Amperex Technology (Hong Kong) Limited, Hong Kong (CN)

(72) Inventors: Changsong CHEN, Ningde (CN); Guodong CHEN, Ningde (CN); Bao TU, Ningde (CN); Xiao LIU, Ningde (CN); Wenming GUO, Ningde (CN); Yongsheng GUO, Ningde (CN); Chuying OUYANG, Ningde (CN)

(73) Assignee: Contemporary Amperex Technology (Hong Kong) Limited, Hong Kong (CN)

(21) Appl. No.: 19/180,189

(22) Filed: Apr. 16, 2025

Related U.S. Application Data
(63) Continuation of application No. PCT/CN2023/070213, filed on Jan. 3, 2023.

(51) Int. Cl. H10K 30/87; H10K 30/40

(52) U.S. Cl. CPC H10K 30/87; H10K 30/40

(57) ABSTRACT

A perovskite solar cell includes a first electrode, a first charge transport layer, a perovskite absorption layer, a second charge transport layer, and a second electrode. The first charge transport layer is arranged on a side of the first electrode; the perovskite absorption layer is arranged on a side of the first charge transport layer away from the first electrode; the second charge transport layer is arranged on a side of the perovskite absorption layer away from the first charge transport layer; and the second electrode is arranged on a side of the second charge transport layer away from the perovskite absorption layer. where the perovskite absorption layer, the second charge transport layer, and the second electrode meet the following relations: d=kλ/2n₁ and n₁²=an₂×n₀.

### CROSS-REFERENCE TO RELATED APPLICATION

This application is a bypass continuation of International Application No. PCT/CN2023/070213, having an international filing date of Jan. 3, 2023, the entire contents of which are incorporated herein by reference.

### TECHNICAL FIELD

This application relates to the field of solar cells, and specifically to a perovskite solar cell and a preparation method thereof, and an electrical apparatus.

### BACKGROUND

Perovskite solar cells have attracted wide attention due to their excellent photoelectric properties, for example, adjustable band gap, high light absorption coefficient, long carrier lifetime and diffusion length, high defect tolerance, and low-cost low-temperature liquid phase preparation method.

However, part of light incident into a cell device undergoes energy deposition in a perovskite absorption layer, while the remaining part penetrates through the layer, causing light loss.

### SUMMARY

In view of the technical problem existing in the background, this application provides a perovskite solar cell, aiming to alleviate the problem of light loss caused by part of incident light penetrating a perovskite absorption layer during use of existing perovskite solar cells.

To achieve the foregoing objective, a first aspect of this application provides a perovskite solar cell, including:
a first electrode;
a first charge transport layer, where the first charge transport layer is arranged on a side of the first electrode;
a perovskite absorption layer, where the perovskite absorption layer is arranged on a side of the first charge transport layer away from the first electrode;
a second charge transport layer, where the second charge transport layer is arranged on a side of the perovskite absorption layer away from the first charge transport layer; and
a second electrode, where the second electrode is arranged on a side of the second charge transport layer away from the perovskite absorption layer;
where the perovskite absorption layer, the second charge transport layer, and the second electrode meet the following relations:

$$d = k λ / 2 {n}_{1} and {n}_{1}^{2} = {an}_{2} \times {n}_{0} ,$$

where d represents a thickness of the second charge transport layer in nm;
k is a positive integer;
λ represents a wavelength of a main band of light absorbed by the perovskite absorption layer in nm;
n₀ is a refractive index of the perovskite absorption layer;
n₁ is a refractive index of the second charge transport layer;
n₂ is a refractive index of the second electrode; and
a is a correction factor with a value of 0.5 to 1.5.

Compared to the prior art, this application at least includes the following beneficial effects: In the perovskite solar cell of this application, the perovskite absorption layer, the second charge transport layer, and the second electrode meet both of the following relations: d=kλ/2n₁ and n₁²=an₂×n₀, so that the second charge transport layer in the perovskite cell has excellent enhanced reflection effect, and thus part of light passing through the perovskite absorption layer can be reflected back to the perovskite absorption layer through the second charge transport layer, increasing a quantity of carriers in the perovskite absorption layer, and increasing a cell current. In this way, the perovskite solar cell of this application has a higher power conversion efficiency.

In some embodiments of this application, the refractive index n₀ of the perovskite absorption layer ranges from 0.5 to 3.

In some embodiments of this application, the refractive index n₁ of the second charge transport layer ranges from 0.5 to 3.

In some embodiments of this application, the refractive index n₂ of the second electrode ranges from 0.5 to 3.

In some embodiments of this application, the second charge transport layer includes a radioactive material. In this way, the refractive index of the second charge transport layer can be adjusted; and the radioactive material has radioactivity, and high-energy radiation particles therein can self-stimulate to generate carriers, increasing a quantity of carriers, thereby increasing the cell current.

In some embodiments of this application, based on a total mass of the second charge transport layer, a percentage of the radioactive material in the second charge transport layer does not exceed 30 wt %, and optionally ranges from 3 wt % to 15 wt %. In this way, the carriers and the cell current can be increased.

In some embodiments of this application, the radioactive material includes at least one of a-type radiation source material and β-type radiation source material. In this way, the carriers and the cell current can be increased.

In some embodiments of this application, the α-type radiation source material includes at least one of ²¹⁰Po and compounds thereof, ²²⁸Th and compounds thereof, ²³⁵U and compounds thereof, ²³⁸Pu and compounds thereof, ²⁴¹Am and compounds thereof, ²⁴²Cm and compounds thereof, and ²⁴⁴Cm and compounds thereof. In this way, the carriers and the cell current can be increased.

In some embodiments of this application, the β-type radiation source material includes at least one of (C₄H₃³H₅⁻)n, ³H₂, Ti³H₄, ¹⁴C and compounds thereof, ³⁵S and compounds thereof, ⁶³Ni and compounds thereof, ⁹⁰Sr and compounds thereof, ⁹⁹Tc and compounds thereof, ¹⁰⁶Ru and compounds, ¹³⁷Cs and compounds thereof, ¹⁴⁴Ce and compounds thereof, ¹⁴⁷Pm and compounds thereof, ¹⁵¹Sm and compounds thereof, and ²²⁶Ra and compounds thereof. In this way, the carriers and the cell current can be increased.

In some embodiments of this application, the second charge transport layer is an electron transport layer, and the first charge transport layer is a hole transport layer, where an electron transport material in the electron transport layer includes at least one of imide compounds, quinone compounds, fullerenes and derivatives thereof, metal oxides, silicon oxides, strontium titanate, calcium titanate, lithium fluoride, and calcium fluoride, and a metal element in the metal oxides includes at least one of Mg, Cd, Zn, In, Pb, W, Sb, Bi, Hg, Ti, Ag, Mn, Fe, V, Sn, Zr, Sr, Ga, and Cr.

In some embodiments of this application, the second charge transport layer is a hole transport layer, and the first charge transport layer is an electron transport layer, where a hole transport material in the hole transport layer includes 2,2′,7,7′-tetra(N,N-para-methoxyaniline)-9,9′-spirobifluorene, methoxytriphenylamine-fluoroformamidine, poly[bis(4-phenyl)(2,4,6-trimethylphenyl)amine], poly(3,4-ethylenedioxythiophene), polystyrene sulfonic acid, poly(3-hexylthiophene), triphenylamine with triptycene as the core, 3,4-ethylenedioxythiophene-methoxytriphenylamine, N-(4-anilino) carbazole-spirobifluorene, polythiophene, phosphate-based monomers, carbazole-based monomers, sulfonic acid-based monomers, triphenylamine-based monomers, aromatic monomers, metal oxides, and cuprous thiocyanate, and a metal element in the metal oxides includes at least one of Ni, Mo, and Cu.

In some embodiments of this application, the perovskite solar cell further includes a buffer layer, where the buffer layer is arranged between the second charge transport layer and the perovskite absorption layer. In this way, the damage to the perovskite absorption layer caused by high-energy radiation particles radiated by the radioactive material in the second charge transport layer can be reduced.

In some embodiments of this application, a valence band maximum and a conduction band minimum of a material of the buffer layer is at least 2.5 eV apart. In this way, the buffer layer may absorb high-energy particles radiated by the radioactive material in the second charge transport layer, thereby reducing the damage to the perovskite absorption layer.

In some embodiments of this application, the material of the buffer layer includes at least one of an inorganic wide bandgap semiconductor material and an organic wide bandgap semiconductor material. In this way, the damage to the perovskite absorption layer can be reduced.

In some embodiments of this application, the inorganic wide bandgap semiconductor material includes at least one of an II-VI group compound semiconductor, an III-V group compound semiconductor, transition metal oxides, transition metal halides, and a silicon-based wide bandgap semiconductor. In this way, the damage to the perovskite absorption layer can be reduced.

In some embodiments of this application, the organic wide bandgap semiconductor material includes at least one of C60, PC61BM ((6,6)-phenyl-C61-butyric acid methyl ester), PC71BM ((6,6)-phenyl-C71-butyric acid methyl ester), P3HT (poly(3-hexylthiophene)), PTAA (poly[bis(4-phenyl)(2,4,6-trimethylphenyl)amine]), and PEDOT:PSS (poly(3,4-ethylenedioxythiophene)-poly(styrenesulfonate)). In this way, the damage to the perovskite absorption layer can be reduced.

In some embodiments of this application, a refractive index n₃ of the buffer layer, the refractive index n1 of the second charge transport layer, and the refractive index n₂ of the second electrode meet the following relation: n₁²=bn₂×n₃, where b is a correction factor with a value of 0.5 to 1.5. In this way, the transmittance of incident light can be improved, and the power conversion efficiency of the cell can be improved.

In some embodiments of this application, the refractive index n₃ of the buffer layer ranges from 0.5 to 3. In this way, the transmittance of incident light can be improved, and the power conversion efficiency of the cell can be improved.

In some embodiments of this application, a thickness of the buffer layer does not exceed 10 nm. In this way, the transmittance of incident light can be improved, and the power conversion efficiency of the cell can be improved.

A second aspect of this application provides a preparation method of perovskite solar cell, including:
forming a first charge transport layer on a side of a first electrode;
forming a perovskite absorption layer on a side of the first charge transport layer away from the first electrode;
forming a second charge transport layer on a side of the perovskite absorption layer away from the first charge transport layer; and
forming a second electrode on a side of the second charge transport layer away from the perovskite absorption layer;
where the perovskite absorption layer, the second charge transport layer, and the second electrode meet the following relation:
d=kλ/2n₁, and n₁²=an₂×n₀,
where d represents a thickness of the second charge transport layer in nm;
k is a positive integer;.
λrepresents a wavelength of a main band of light absorbed by the perovskite absorption layer in nm;
n₀ is a refractive index of the perovskite absorption layer;
n₁ is a refractive index of the second charge transport layer;
n₂ is a refractive index of the second electrode; and
a is a correction factor with a value of 0.5 to 1.5.

In this way, using the method of this application, the above-described perovskite solar cell with excellent power conversion efficiency can be prepared.

In some embodiments of this application, the preparation method of perovskite solar cell further includes: forming a buffer layer between the second charge transport layer and the perovskite absorption layer. In this way, the damage to the perovskite absorption layer caused by high-energy radiation particles radiated by the radioactive material in the second charge transport layer can be reduced.

A third aspect of this application provides an electrical apparatus, including the perovskite solar cell according to the first aspect or a perovskite solar cell prepared by the method according to the second aspect, where the perovskite solar cell is configured to provide electrical energy.

The foregoing description is merely an overview of the technical solution of this application. To more clearly understand the technical means in this application so that they can be implemented according to the content of the specification, and to make the above and other objectives, features, and advantages of this application more obvious and easier to understand, the following describes specific embodiments of this application.

### BRIEF DESCRIPTION OF DRAWINGS

Persons of ordinary skill in the art can clearly understand various other advantages and benefits by reading the detailed description of the preferred embodiments below. The accompanying drawings are merely intended to illustrate the preferred embodiments and are not intended to limit this application. In addition, in all the accompanying drawings, same components are denoted by same reference signs. In the accompanying drawings:

FIG. 1 is a schematic structural diagram of a perovskite solar cell in the prior art.

FIG. 2 is a schematic structural diagram of a perovskite solar cell according to an embodiment of this application.

FIG. 3 is a schematic structural diagram of a perovskite solar cell according to another embodiment of this application.

FIG. 4 is a diagram showing a working principle of a perovskite solar cell according to another embodiment of this application.

### DESCRIPTION OF REFERENCE SIGNS

1000: perovskite solar cell; 100: first electrode; 200: first charge transport layer; 300: perovskite absorption layer; 400: second charge transport layer; 500: second electrode; and 600: buffer layer.

### DESCRIPTION OF EMBODIMENTS

The following describes in detail the embodiments of technical solutions of this application in detail. The following embodiments are merely intended for a clearer description of the technical solutions of this application and therefore are used as just examples which do not constitute any limitations on the protection scope of this application.

In this specification, reference to “embodiment” means that specific features, structures or characteristics described with reference to the embodiment may be incorporated in at least one embodiment of this application. The word “embodiment” appearing in various places in the specification does not necessarily refer to the same embodiment or an independent or alternative embodiment that is exclusive of other embodiments. Persons skilled in the art explicitly and implicitly understand that the embodiments described herein may be combined with other embodiments.

For brevity, this specification specifically discloses only some numerical ranges. However, any lower limit may be combined with any upper limit to form an unspecified range, and any lower limit may be combined with another lower limit to form an unspecified range, and likewise, any upper limit may be combined with any other upper limit to form an unspecified range. In addition, each individually disclosed point or individual single numerical value may itself be a lower limit or an upper limit which can be combined with any other point or individual numerical value or combined with another lower limit or upper limit to form a range not expressly recorded.

In the description of the embodiments of this application, the term “and/or” is only an associative relationship for describing associated objects, indicating that three relationships may be present. For example, A and/or B may indicate the following three cases: presence of only A, presence of both A and B, and presence of only B. In addition, a character “/” in this specification generally indicates an “or” relationship between contextually associated objects.

Unless otherwise defined, all technical and scientific terms used herein shall have the same meanings as commonly understood by persons skilled in the art to which this application relates. The terms used herein are intended to merely describe the specific embodiments rather than to limit this application. The terms “include/comprise” and “have” and any other variations thereof in the specification, claims, and brief description of drawings of this application are intended to cover non-exclusive inclusions.

Perovskite solar cells have attracted wide attention due to their excellent photoelectric properties, for example, adjustable band gap, high light absorption coefficient, long carrier lifetime and diffusion length, high defect tolerance, and low-cost low-temperature liquid phase preparation method.

As shown in FIG. 1, an existing perovskite solar cell includes an upper electrode, a charge transport layer, a perovskite layer, a charge transport layer, and a lower electrode. Incident light enters from above the upper electrode, part of the light undergoes energy deposition in the perovskite absorption layer, and the remaining part penetrates through the layer, causing light loss, which reduces the power conversion efficiency of the cell.

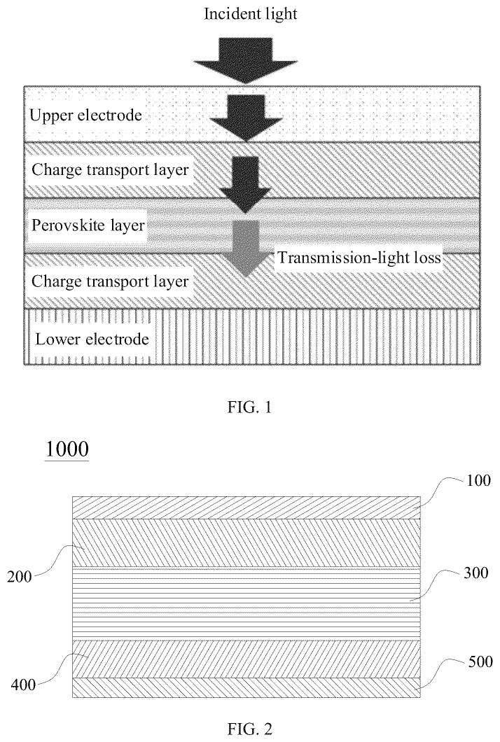

Therefore, a first aspect of this application discloses a perovskite solar cell. Referring to FIG. 2, the perovskite solar cell 1000 include a first electrode 100, a first charge transport layer 200, a perovskite absorption layer 300, a second charge transport layer 400, and a second electrode 500. The first charge transport layer 200 is arranged on a side of the first electrode 100; the perovskite absorption layer 300 is arranged on a side of the first charge transport layer 200 away from the first electrode 100; the second charge transport layer 400 is arranged on a side of the perovskite absorption layer 300 away from the first charge transport layer 200; and the second electrode 500 is arranged on a side of the second charge transport layer 400 away from the perovskite absorption layer 300; where the perovskite absorption layer 300, the second charge transport layer 400, and the second electrode 500 meet the following relations: d=kλ/2n₁ and n₁²=an₂×n₀, where d represents a thickness of the second charge transport layer 400 in nm; k is a positive integer; λ represents wavelength of a main band of light absorbed by the perovskite absorption layer 300 in nm; n₀ is a refractive index of the perovskite absorption layer 300; n₁ is a refractive index of the second charge transport layer 400; n₂ is a refractive index of the second electrode 500; and a is a correction factor with a value of 0.5 to 1.5, for example, 0.5, 0.6, 0.7, 0.8, 0.9, 1.0, 1.1, 1.2, 1.3, 1.4, and 1.5.

Through extensive research, the inventors found that in the perovskite solar cell of this application, the perovskite absorption layer, the second charge transport layer, and the second electrode meet both of the following relations: d=kλ/2n₁ and n₁²=an₂×n₀, so that the second charge transport layer in the perovskite cell has excellent enhanced reflection effect, and thus part of light passing through the perovskite absorption layer can be reflected back to the perovskite absorption layer through the second charge transport layer, increasing a quantity of carriers in the perovskite absorption layer, and increasing a cell current. In this way, the perovskite solar cell of this application has a higher power conversion efficiency.

According to some examples, a method for testing “a wavelength λ of the main band of light absorbed by the perovskite absorption layer 300” includes: at room temperature, test a perovskite solid film sample using an ultraviolet-visible spectrophotometer (Shimadzu UV-Vis 3200), obtaining an absorption spectrum in a visible light band, and taking a wavelength corresponding to a band with a maximum absorption value in the absorption spectrum as the wavelength λ of the main band of light aborted; and methods for testing “the refractive index n₂ of the second electrode 500”, “the refractive index n₁ of the second charge transport layer 400”, and “the refractive index no of the perovskite absorption layer 300” include: at room temperature, measuring solid film samples using a refractometer (Mettler Toledo R5) to directly obtain the refractive index.

Through in-depth research, the inventors of this application found that when the perovskite solar cell of this application meets the preceding conditions, and optionally meets one or more of the following conditions, the power conversion efficiency of the cell can be further improved.

In some embodiments, electrode materials of the first electrode 100 and the second electrode 500 may include an organic conductive material, an inorganic conductive material, or an organic-inorganic hybrid conductive material. For example, the organic conductive material includes but is not limited to PEDOT (polymer of 3,4-ethylenedioxythiophene), polythiophene, and polyacetylene. The inorganic conductive material includes but is not limited to FTO (fluorine-doped SnO₂ conductive glass), ITO (indium tin oxide), AZO (aluminum-doped zinc oxide transparent conductive glass), metal, and carbon derivatives.

In some embodiments, the refractive index n₂ of the second electrode 500 ranges from 0.5 to 3, for example, from 0.7 to 2.8, from 1 to 2.5, from 1.2 to 2.2, from 1.5 to 2, and from 1.5 to 1.7.

In some embodiments, the refractive index n₁ and thickness d of the second charge transport layer 400 meet the relation d=kλ/2n₁, where k is an integer, for example, 1, 2, 3, and 4. In some other embodiments, with k=1, the refractive index n₁ and thickness d of the second charge transport layer 400 meet the relation d=λ/2n₁. With the same refractive index and incident light, the thickness of the second charge transport layer 400 is relatively low, and correspondingly, an enhanced reflection effect of the second charge transport layer 400 is also relatively high.

In some embodiments, the refractive index n₁ of the second charge transport layer 400 ranges from 0.5 to 3, for example, from 0.7 to 2.8, from 1 to 2.5, from 1.2 to 2.2, from 1.5-2, and from 1.5 to 1.7.

In some embodiments, the refractive index of the second charge transport layer 400 may be adjusted by doping the second charge transport layer 400 with a radioactive material, and by controlling the thickness of the second charge transport layer 400, the refractive index n₁ and thickness d of the second charge transport layer 400 meet the relations d=λ/2n₁ and n₁²=an₂×n₀. The inventors found that, by doping the second charge transport layer 400 with a radioactive material, not only the refractive index of the second charge transport layer can be adjusted, but also high-energy radiation particles in the radioactive material can self-stimulate to generate carriers because the radioactive material in the second charge transport layer 400 has radioactivity, thereby increasing a quantity of carriers in the perovskite solar cell 1000 and increasing the cell current.

In some embodiments, based on a total mass of the second charge transport layer 400, a percentage of the radioactive material does not exceed 30 wt %, for example, ranges from 1 wt % to 30 wt %, from 2 wt % to 29 wt %, from 3 wt % to 28 wt %, from 3 wt % to 25 wt %, from 3 wt % to 22 wt %, from 3 wt % to 20 wt %, from 3 wt % to 18 wt %, from 3 wt % to 15 wt %, from 3 wt % to 12 wt %, and from 3 wt % to 10 wt %. Specifically, the refractive index of the second charge transport layer 400 can be controlled by adjusting the percentage of the radioactive material in the second charge transport layer 400, so that the refractive index n₁ and thickness d of the second charge transport layer 400 meet the relations d=kλ/2n₁ and n₁²=an₂×n₀, so as to achieve the enhanced reflection effect of the second charge transport layer 400. If the percentage of the radioactive material is too high, the high-energy particles radiated by the radioactive material will damage the perovskite absorption layer 300. In some other embodiments, based on the total mass of the second charge transport layer 400, the percentage of the radioactive material ranges from 3 wt % to 15 wt %.

In some embodiments, the radioactive material in the second charge transport layer 400 includes at least one of an α-type radiation source material and a β-type radiation source material. For example, the α-type radiation source material includes at least one of ²¹⁰Po and compounds thereof, ²²⁸Th and compounds thereof, ²³⁵U and compounds thereof, ²³⁸Pu and compounds thereof, ²⁴¹Am and compounds thereof, ²⁴²Cm and compounds thereof, and ²⁴⁴Cm and compounds thereof; and the β-type radiation source material includes at least one of (C₄H₃³H₅⁻)n, ³H₂, Ti₃H₄, ¹⁴C and compounds thereof, ³⁵S and compounds thereof, ⁶³Ni and compounds thereof, ⁹⁰Sr and compounds thereof, ⁹⁹Tc and compounds thereof, ¹⁰⁶Ru and compounds thereof, ¹³⁷Cs and compounds thereof, ¹⁴⁴Ce and compounds thereof, ¹⁴⁷Pm and compounds thereof, ¹⁵¹Sm and compounds thereof, and ²²⁶Ra and compounds thereof.

The perovskite solar cell 1000 of this application may be a regular perovskite solar cell or an inverted perovskite solar cell.

In some embodiments of this application, the perovskite solar cell 1000 is a regular perovskite solar cell, the second charge transport layer 400 is a hole transport layer, and the first charge transport layer 200 is an electron transport layer, where a hole transport material in the hole transport layer includes 2,2′,7,7′-tetra(N,N-para-methoxyaniline)-9,9′-spirobifluorene, methoxytriphenylamine-fluoroformamidine, poly[bis(4-phenyl)(2,4,6-trimethylphenyl)amine], poly(3,4-ethylenedioxythiophene), polystyrene sulfonic acid, poly(3-hexylthiophene), triphenylamine with triptycene as the core, 3,4-ethylenedioxythiophene-methoxytriphenylamine, N-(4-anilino) carbazole-spirobifluorene, polythiophene, phosphate-based monomers, carbazole-based monomers, sulfonic acid-based monomers, triphenylamine-based monomers, aromatic monomers, metal oxides, and cuprous thiocyanate, and a metal element in the metal oxides includes at least one of Ni, Mo, and Cu. An electron transport material in the electron transport layer includes at least one of imide compounds, quinone compounds, fullerenes and derivatives thereof, metal oxides, silicon oxides, strontium titanate, calcium titanate, lithium fluoride, and calcium fluoride, where a metal element in the metal oxides includes at least one of Mg, Cd, Zn, In, Pb, W, Sb, Bi, Hg, Ti, Ag, Mn, Fe, V, Sn, Zr, Sr, Ga, and Cr. Further, the electron transport material in the electron transport layer includes poly(3,4-ethylenedioxythiophene), polystyrene sulfonate, poly[bis (4-phenyl)(2,4,6-trimethylphenyl)amine], NiOx, MoOx, 2,2′,7,7′-tetra(N,N-para-methoxyaniline)-9,9′-spirobifluorene, WO₃, polyethyleneimine, polyethyleneimine, ZnO, TiO₂, [6,6]-phenyl-C61-butyric acid methyl ester, and SnO₂.

In some embodiments, the perovskite solar cell 1000 is an inverted perovskite solar cell, the second charge transport layer 400 is an electron transport layer, and the first charge transport layer 200 is a hole transport layer, where an electron transport material in the electron transport layer includes at least one of imide compounds, quinone compounds, fullerenes and derivatives thereof, metal oxides, silicon oxides, strontium titanate, calcium titanate, lithium fluoride, and calcium fluoride, where a metal element in the metal oxides includes at least one of Mg, Cd, Zn, In, Pb, W, Sb, Bi, Hg, Ti, Ag, Mn, Fe, V, Sn, Zr, Sr, Ga, and Cr. Further, the electron transport rt material in the electron transport layer includes poly(3,4-ethylenedioxythiophene), polystyrene sulfonate, poly[bis(4-phenyl)(2,4,6-trimethylphenyl)amine], NiOx, MoOx, 2,2′,7,7′-tetra(N,N-para-methoxyaniline)-9,9′-spirobifluorene, WO₃, polyethyleneimine, polyethyleneimine, ZnO, TiO₂, [6,6]-phenyl-C61-butyric acid methyl ester, and SnO₂. A hole transport material in the hole transport layer includes 2,2′,7,7′-tetra(N,N-para-methoxyaniline)-9,9′-spirobifluorene, methoxytriphenylamine-fluoroformamidine, poly[bis(4-phenyl)(2,4,6-trimethylphenyl)amine], poly(3,4-ethylenedioxythiophene), polystyrene sulfonic acid, poly(3-hexylthiophene), triphenylamine with triptycene as the core, 3,4-ethylenedioxythiophene-methoxytriphenylamine, N-(4-anilino) carbazole-spirobifluorene, polythiophene, phosphate-based monomers, carbazole-based monomers, sulfonic acid-based monomers, triphenylamine-based monomers, aromatic monomers, metal oxides, and cuprous thiocyanate, and a metal element in the metal oxides includes at least one of Ni, Mo, and Cu.

In some embodiments, the refractive index n₂ of the perovskite absorption layer 300 ranges from 0.5 to 3, for example, from 0.7 to 2.8, from 1 to 2.5, from 1.2 to 2.2, from 1.5 to 2, and from 1.5 to 1.7.

In some embodiments, a perovskite material in the perovskite absorption layer 300 has a chemical formula of ABX₃, where A is an inorganic or organic or organic-inorganic hybrid cation, B is a metal cation, and X is an inorganic or organic or organic-inorganic hybrid anion, for example, A is an organic amine cation, B is a divalent metal cation, and X is a halogen anion or SCN—. In some examples, A in ABX₃ may include at least one of CH₃NH₃⁺ and HC(NH₂)₂⁺; in other words, A may be CH₃NH₃⁺, HC(NH₂)₂⁺, or a mixture of the two in any ratio. It should be understood that A may further include a metal ion, for example, at least one of Cs⁺, Rb⁺, and K⁺. B in ABX₃ may be at least one of Pb²⁺, Sn²⁺, and Ge²⁺. For example, ABX₃ may be CH₃NH₃PbI₃, CH₃NH₃SnI₃, CH₃NH₃PbI₂Cl, CH₃NH₃PbI₂Br, and CH₃NH₃Pb(I₁₋ₓBrₓ)₃ (where 0<x<1).

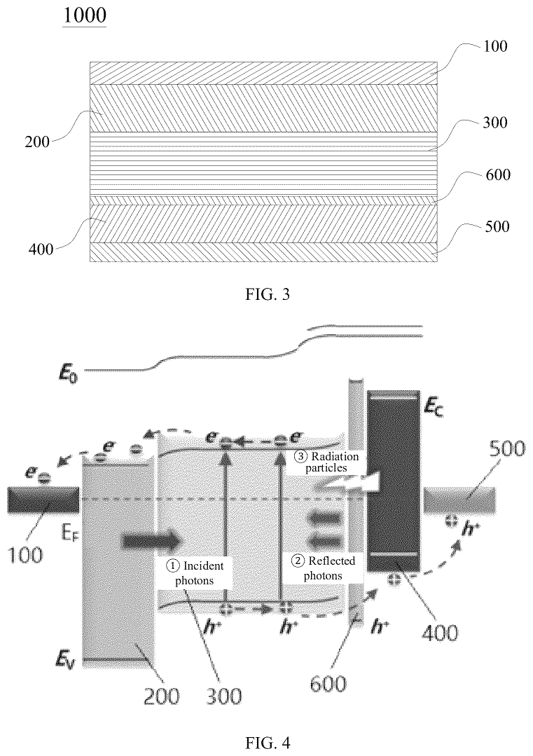

In some embodiments, the high-energy radiation particles in the radioactive material in the second charge transport layer 400 may damage the perovskite absorption layer 300. Therefore, to reduce the damage to the perovskite absorption layer 300, referring to FIG. 3, a buffer layer 600 is arranged between the second charge transport layer 400 and the perovskite absorption layer 300, where a valence band maximum and a conduction band minimum of a material of the buffer layer 600 are at least 2.5 eV apart. In this way, the buffer layer 600 meeting this condition can absorb the high-energy particles radiated by the radioactive material, undergo energy deposition, convert the kinetic energy of the high-energy particles into energy of charge, thereby effectively reducing the damage to the perovskite absorption layer 300.

According to some examples, a method for testing energy band information (valence band maximum, conduction band minimum, or the like) of the material of the buffer layer 600 includes: at room temperature and normal pressure, obtaining an energy band distribution of the material using an X-ray photoelectron spectrometer (XPS) model Escalab 250Xi (from Thermo Scientific), and obtaining a valence band maximum position and a conduction band minimum position from an XPS spectrum.

In some embodiments, a material of the buffer layer 600 includes at least one of an inorganic wide bandgap semiconductor material and an organic wide bandgap semiconductor material, where the inorganic wide bandgap semiconductor material includes at least one of an II-VI group compound semiconductor, an III-V group compound semiconductor, transition metal oxides, transition metal halides, and a silicon-based wide bandgap semiconductor. Specifically, the II-VI group compound semiconductor refers to a compound semiconductor composed of group IIB elements (Zn, Cd, Hg) and group VIA elements (S, Se, Te, O) in the periodic table, for example, ZnS, ZnSe, ZnTe, CdS, CdSe, CdTe, HgS, HgSe, and HgTe. The III-V group compound semiconductor refers to a compound semiconductor composed of group IIIA elements (B, Al, Ga, In) and group VA elements (N, P, As, Sb) in the periodic table, for example, BN, BP, BAs, BSb, AlN, AlP, AlAs, AlSb, GaN, GaP, GaAs, GaSb, InAs, InN, InP, and InSb. The transition metal oxides include but are not limited to chromium oxide, manganese oxide, iron oxide, cobalt oxide, nickel oxide, copper oxide, zinc oxide, palladium oxide, silver oxide, platinum oxide. The transition metal halides include but are not limited to chromium chloride, manganese chloride, iron chloride, cobalt chloride, nickel chloride, copper chloride, zinc chloride, palladium chloride, silver chloride, platinum chloride, chromium bromide, manganese bromide, iron bromide, cobalt bromide, nickel bromide, copper bromide, zinc bromide, palladium bromide, silver bromide, platinum bromide. The silicon-based wide bandgap semiconductor includes silicon nitride and silicon carbide. The organic wide bandgap semiconductor material includes at least one of C60, PC61BM ((6,6)-phenyl-C61-butyric acid methyl ester), PC71BM ((6,6)-phenyl-C71-butyric acid methyl ester), P3HT (poly(3-hexylthiophene)), PTAA (poly[bis(4-phenyl)(2,4,6-trimethylphenyl)amine]), and PEDOT:PSS (poly(3,4-ethylenedioxythiophene)-poly(styrenesulfonate)).

In some embodiments, a thickness of the buffer layer 600 does not exceed 10 nm, for example, ranges from 2 nm to 10 nm, from 2 nm to 8 nm, from 2 nm to 6 nm, from 2 nm to 4 nm, or from 2 nm to 3 nm. In this way, incident light reflection can be reduced and the power conversion efficiency of the cell can be improved.

In some embodiments, a refractive index n₃ of the buffer layer 600, the refractive index n₁ of the second charge transport layer 400, and the refractive index n₂ of the second electrode 500 meet the following relation: n₁²=bn₂×n₃, where b is a correction factor with a value of 0.5 to 1.5, for example, 0.5, 0.6, 0.7, 0.8, 0.9, 1.0, 1.1, 1.2, 1.3, 1.4, and 1.5. The refractive index no of the buffer layer 600 ranges from 0.5 to 3, for example, from 0.7 to 2.8, from 1 to 2.5, from 1.2 to 2.2, from 1.5 to 2, and from 1.5 to 1.7; and the refractive index n₂ of the second electrode 500 ranges from 0.5 to 3, for example, from 0.7 to 2.8, from 1 to 2.5, from 1.2 to 2.2, from 1.5 to 2, and from 1.5 to 1.7. The inventors found that when the refractive index n₃ of the buffer layer 600, the refractive index n₁ of the second charge transport layer 400, and the refractive index n₂ of the second electrode 500 meet the foregoing relation, a system composed of the second electrode 500, the second charge transport layer 400, and the buffer layer 600 can improve the reflectivity of the second charge transport layer 400, so that part of the light passing through the perovskite absorption layer 300 can be reflected back to the perovskite absorption layer 300 through the second charge transport layer 400, increasing a quantity of photogenerated carriers in the perovskite absorption layer 300 and increasing the cell current.

According to some examples, a method for testing the refractive index n₃ of the buffer layer 600 includes: at room temperature, measuring solid film samples using a refractometer (Mettler Toledo R5) to directly obtain the refractive index.

Specifically, referring to FIG. 4, the perovskite solar cell 1000 includes a first electrode 100, a first charge transport layer 200, a buffer layer 600, a perovskite absorption layer 300, a second charge transport layer 400, and a second electrode 500. The second charge transport layer 400 being a hole transport layer and the first charge transport layer 200 being an electron transport layer are used as an example, and the perovskite absorption layer 300, the second charge transport layer 400, the second electrode 500, and the buffer layer 600 meet all the relations: d=kλ/2n₁, n₁²=an₂×n₀, and n₁²=bn₂×n₃. The incident light enters from the side of the first electrode 100, passes through the first charge transport layer 200, and enters the perovskite absorption layer 300; the perovskite material in the perovskite absorption layer 300 absorbs the incident photons to generate electron-hole pairs; and the electron-hole pairs dissociate to form free carriers, where the free electrons are transmitted to the first electrode 100 through the first charge transport layer 200, and the free electron holes are transmitted to the second electrode 500 through the second charge transport layer 400. Due to the excellent enhanced reflection effect of the second charge transport layer 400, part of the light passing through the perovskite absorption layer 300 is reflected back to the perovskite absorption layer 300 by the second charge transport layer 400, increasing a quantity of carriers in the perovskite absorption layer 300 and increasing the cell current. In addition, the radioactive material in the second charge transport layer 400 has radioactivity, and its high-energy radiation particles can self-stimulate to generate carriers, increasing a quantity of carriers, thereby further increasing the cell current. The buffer layer 600 arranged between the second charge transport layer 400 and the perovskite absorption layer 300 can reduce the damage of high-energy radiation particles from the radioactive material in the second charge transport layer 400 to the perovskite absorption layer 300.

A second aspect of this application provides a preparation method of perovskite solar cell, including:
S1: Form a first charge transport layer on a side of a first electrode.
S2: Form a perovskite absorption layer on a side of the first charge transport layer away from the first electrode.
S3: Form a second charge transport layer on a side of the perovskite absorption layer away from the first charge transport layer.
S4: Form a second electrode on a side of the second charge transport layer away from the perovskite absorption layer;

In the perovskite solar cell of this application, the perovskite absorption layer, the second charge transport layer, and the second electrode meet both of the following relations: d=kλ/2n₁ and n₁²=an₂×n₀, so that the second charge transport layer in the perovskite cell has excellent enhanced reflection effect, and thus part of light passing through the perovskite absorption layer can be reflected back to the perovskite absorption layer through the second charge transport layer, increasing a quantity of carriers in the perovskite absorption layer, and increasing a cell current. In this way, the perovskite solar cell obtained using the method of this application has relatively high power conversion efficiency.

In some embodiments, the forming a first charge transport layer in Step S1, the forming a perovskite absorption layer in Step S2, the forming a second charge transport layer in Step S3, and the forming a second electrode in Step S4 may use chemical bath deposition, electrochemical deposition, chemical vapor deposition, physical epitaxial growth, thermal evaporation co-evaporation, atomic layer deposition, magnetron sputtering, precursor liquid spin coating, precursor liquid slit coating, precursor liquid blade coating, mechanical pressing, and the like, where thermal evaporation co-evaporation and precursor liquid coating (spin coating) are preferred.

In some embodiments, the refractive index n₁ of the second charge transport layer may be adjusted by doping the second charge transport layer with a radioactive material, and by controlling the thickness of the second charge transport layer, the refractive index n₁ and thickness d of the second charge transport layer meet the relations d=kλ/2n₁ and n₁²=an₂×n₀. The inventors found that by doping the second charge transport layer with a radioactive material, not only the refractive index of the second charge transport layer can be adjusted, but also high-energy radiation particles in the radioactive material can self-stimulate to generate carriers because the radioactive material in the second charge transport layer has radioactivity, thereby increasing a quantity of carriers in the perovskite solar cell and increasing the cell current.

In an example, co-evaporation or magnetron sputtering can be used to form the second charge transport layer including radioactive materials and charge transport layer materials on a side of the perovskite absorption layer.

In this way, using the method of this application, the above-described perovskite solar cell with excellent power conversion efficiency can be prepared.

In some embodiments of this application, the high-energy radiation particles in the radioactive material in the second charge transport layer may damage the perovskite absorption layer. Therefore, to reduce the damage to the perovskite absorption layer, a buffer layer is formed between the second charge transport layer and the perovskite absorption layer, where a valence band maximum and a conduction band minimum of a material of the buffer layer are at least 2.5 eV apart. In this way, the buffer layer meeting this condition can absorb the high-energy particles radiated by the radioactive material, undergo energy deposition, and convert the kinetic energy of the high-energy particles into energy of charge, thereby effectively reducing the damage to the perovskite absorption layer.

In an example, a method of forming a buffer layer between the second charge transport layer and the perovskite absorption layer may use an evaporation method.

It should be noted that the first electrode, radioactive material, charge transport material, buffer layer, and second electrode used in the preparation method of perovskite solar cell are the same as described above and will not be repeated herein.

A third aspect of this application provides an electrical apparatus, including the perovskite solar cell according to the first aspect or a perovskite solar cell prepared by the method according to the second aspect, where the perovskite solar cell is configured to provide electrical energy. In an example, the electrical apparatus may be a lighting element, a display element, a vehicle, or the like.

To describe the technical problems solved by the embodiments of this application, technical solutions, and beneficial effects more clearly, the following further provides descriptions in detail with reference to the embodiments and accompanying drawings. Apparently, the described embodiments are only some but not all of the embodiments of this application. The following description of at least one exemplary embodiment is merely illustrative and definitely is not construed as any limitation on this application or on use of this application. All other embodiments obtained by persons of ordinary skill in the art based on the embodiments of this application without creative efforts shall fall within the protection scope of this application.

### Example 1

The preparation method of perovskite solar cell included the following steps:

(1) The surface of FTO conductive glass with a dimension of 2.0 cm×2.0 cm was cleaned with acetone and isopropanol twice in sequence; and next the FTO conductive glass was immersed in deionized water, ultrasonicated for 10 minutes, then dried in a blowing drying oven, and placed in a glove box (N2 atmosphere), served as a first electrode.

(2) Preparing an electron transport layer: A concentration of 3 wt % SnO₂ nanocolloidal aqueous solution was spin applied on the first electrode at a speed of 4000 rpm to 6500 rpm, and then the resulting coated electrode was transferred to a constant temperature hot plate, heated at 150° C. for 15 minutes, and cooled to room temperature to form an electron transport layer on the first electrode with a thickness of 30 nm.

(3) Preparing a perovskite absorption layer: A concentration of 1.5 mol/L FAPbI₃ DMF solution was spin applied on the electron transport layer obtained in Step 2 at a speed of 3000 rpm to 4500 rpm, and then the coated electrode was transferred to a constant temperature hot plate, heated at 100° C. for 30 minutes, and cooled to room temperature to form a perovskite absorption layer on the electron transport layer, with a thickness of 500 nm. The perovskite absorption layer with no of 2.59 absorbed the main band 2 of light absorbed with a wavelength of 700 nm.

(4) Preparing a hole transport layer: A chlorobenzene solution of Spiro-OMeTAD (2,2′,7,7′-tetra(N,N-para-methoxyaniline)-9,9′-spirobifluorene) with a concentration of 73 mg/mL was spin applied on the perovskite absorption layer at a speed of 3000 rpm, with a spin coating time of 20 seconds, to obtain a hole transport layer with a thickness of 180.4 nm and a refractive index n₁ of 1.94.

(5) Preparing a second electrode: The sample obtained in Step (4) was placed into a vacuum coating machine, and Ag electrode evaporation was performed on the surface of the hole transport layer obtained under a vacuum condition of 5×10⁻⁴ Pa, at an evaporation rate of 0.1 Å/s. The Ag electrode had a thickness of 80 nm and served as the second electrode with a refractive index n₂ of 1.48.

The preparation methods of perovskite solar cell in Example 2 and Example 3 are the same as that in Example 1, with differences as shown in Table 1.

TABLE 1

| | Perovskite absorption layer | | | Hole transport layer | | | Second electrode | |
|---|---|---|---|---|---|---|---|---|
| | | Thickness | Refractive | | Refractive | Thickness | | Refractive |
| | Composition | (nm) | index n₀ | Composition | index n₁ | (nm) | Composition | index n₂ |
| Example | FAPbI₃ | 500 | 2.59 | Spiro- | 1.94 | 180.4 | Ag | 1.48 |
| 1 | | | | OMeTAD | | | | |
| Example | FAPbI₃ | 500 | 2.59 | P3HT | 2.08 | 168.3 | Ag | 1.48 |
| 2 | | | | | | | | |
| Example | FAPbI₃ | 500 | 2.59 | MoO₃ | 2.1 | 166.7 | Ag | 1.48 |
| 3 | | | | | | | | |

### Example 4

The preparation method of perovskite solar cell included the following steps:

(1) The surface of FTO conductive glass with a dimension of 2.0 cm×2.0 cm was cleaned with acetone and isopropanol twice in sequence; and next the FTO conductive glass was immersed in deionized water, ultrasonicated for 10 minutes, then dried in a blowing drying oven, and placed in a glove box (N2 atmosphere), served as a first electrode.

(2) Preparing an electron transport layer: A concentration of 3 wt % SnO₂ nanocolloidal aqueous solution was spin applied on the first electrode at a speed of 4000 rpm to 6500 rpm, and then the resulting coated electrode was transferred to a constant temperature hot plate, heated at 150° C. for 15 minutes, and cooled to room temperature to form an electron transport layer on the first electrode with a thickness of 30 nm.

(3) Preparing a perovskite absorption layer: A concentration of 1.5 mol/L FAPbI₃ DMF solution was spin applied on the electron transport layer obtained in Step 2 at a speed of 3000 rpm to 4500 rpm, and then the coated electrode was transferred to a constant temperature hot plate, heated at 100° C. for 30 minutes, and cooled to room temperature to form a perovskite absorption layer on the electron transport layer, with a thickness of 500 nm. The perovskite absorption layer with no of 2.59 absorbed the main band λ of light absorbed with a wavelength of 700 nm.

(4) Preparing a buffer layer: The sample obtained in Step 3 was placed into a vacuum coating machine, and CuI evaporation was performed on the surface of the perovskite absorption layer obtained under a vacuum condition of 5×10⁻⁴ Pa, with a thickness of 3 nm and a refractive index n₀ of 2.63.

(5) Preparing a hole transport layer: The sample obtained in Step (4) was placed into a vacuum coating machine, and ⁶³NiClₓ (x≥2) and CuO co-evaporation were performed on the surface of the buffer layer obtained under a vacuum condition of 5×10⁻⁴ Pa, to form an electron transport layer, where ⁶³NiClₓ accounted for 5 wt % of the electron transport layer, the thickness of the hole transport layer was d=176.8 nm, and the refractive index n₁ was 1.98 (d=kλ/2n₁, k=1).

(6) Preparing a second electrode: The sample obtained in Step (5) was placed into a vacuum coating machine, and Ag electrode evaporation was performed on the surface of the hole transport layer obtained under a vacuum condition of 5×10⁻⁴ Pa, at an evaporation rate of 0.1 Å/s. The Ag electrode had a thickness of 80 nm and served as the second electrode with a refractive index n₂ of 1.48.

The preparation methods of perovskite solar cell in Examples 4 to 21 were the same as that in Example 1, with differences as shown in Table 2.

In the comparative example, the preparation methods of the first electrode, electron transport layer, perovskite absorption layer, and second electrode of the perovskite solar cell were the same as those in Example 1, except that there was no hole transport layer and buffer layer, and the step of preparing the hole transport layer included: A chlorobenzene solution of Spiro-OMeTAD (2,2′,7,7′-tetra(N,N-para-methoxyaniline)-9,9′-spirobifluorene) with a concentration of 73 mg/mL was spin applied on the perovskite absorption layer at a speed of 3000 rpm, with a spin coating time of 20 seconds, to obtain a hole transport layer with a thickness of 150 nm.

TABLE 2

| | | | | Hole transport layer | | | | | | Perovskite |
|---|---|---|---|---|---|---|---|---|---|---|
| | | | | | Percentage of | | | | | absorption |
| | Buffer layer | | | Composition of | radioactive | | | Second electrode | | layer |
| | | Thickness | Refractive | radioactive | material | Refractive | Thickness | | Refractive | Refractive |
| | Composition | (nm) | index n₃ | material | (wt %) | index n₁ | (nm) | Composition | index n₂ | index n₀ |
| Example 4 | CuI | 3 | 2.63 | ⁶³NiClₓ | 5 | 1.98 | 176.8 | Ag | 1.48 | 2.59 |
| Example 5 | CuI | 3 | 2.63 | ⁶³NiClₓ | 10 | 2.05 | 170.7 | Ag | 1.48 | 2.59 |
| Example 6 | CuI | 3 | 2.63 | ⁶³NiClₓ | 3 | 1.96 | 178.6 | Ag | 1.48 | 2.59 |
| Example 7 | CuI | 3 | 2.63 | ⁶³NiClₓ | 15 | 2.10 | 166.7 | Ag | 1.48 | 2.59 |
| Example 8 | CuI | 3 | 2.63 | ⁶³NiClₓ | 20 | 2.14 | 163.6 | Ag | 1.48 | 2.59 |
| Example 9 | CuI | 3 | 2.63 | ⁶³NiClₓ | 30 | 2.23 | 157.0 | Ag | 1.48 | 2.59 |
| Example 10 | CuI | 3 | 2.63 | ³⁵S | 10 | 2.08 | 168.3 | Ag | 1.48 | 2.59 |
| Example 11 | CuI | 3 | 2.63 | ¹⁴C | 10 | 2.06 | 169.9 | Ag | 1.48 | 2.59 |
| Example 12 | CuI | 3 | 2.63 | Ti₃H₄ | 10 | 2.09 | 167.5 | Ag | 1.48 | 2.59 |
| Example 13 | PC61BM | 3 | 2.30 | ⁶³NiClₓ | 10 | 2.05 | 170.7 | Ag | 1.48 | 2.59 |
| Example 14 | PEDOT:PSS | 3 | 3.2 | ⁶³NiClₓ | 10 | 2.05 | 170.7 | Ag | 1.48 | 2.59 |
| Example 15 | ZnS | 3 | 2.35 | ⁶³NiClₓ | 10 | 2.05 | 170.7 | Ag | 1.48 | 2.59 |
| Example 16 | CdSe | 3 | 2.56 | ⁶³NiClₓ | 10 | 2.05 | 170.7 | Ag | 1.48 | 2.59 |
| Example 17 | BN | 3 | 2.11 | ⁶³NiClₓ | 10 | 2.05 | 170.7 | Ag | 1.48 | 2.59 |
| Example 18 | CuI | 10 | 2.14 | ⁶³NiClₓ | 10 | 2.05 | 170.7 | Ag | 1.48 | 2.59 |
| Example 19 | CuI | 8 | 2.14 | ⁶³NiClₓ | 10 | 2.05 | 170.7 | Ag | 1.48 | 2.59 |
| Example 20 | CuI | 6 | 2.14 | ⁶³NiClₓ | 10 | 2.05 | 170.7 | Ag | 1.48 | 2.59 |
| Example 21 | / | / | / | ⁶³NiClx | 10 | 2.05 | 170.7 | Ag | 1.48 | 2.59 |
| Comparative | / | / | / | / | / | 1.94 | 150 | Ag | 1.48 | 2.59 |
| Example | | | | | | | | | | |

Performance tests were conducted on the perovskite solar cells of Examples 1 to 21 and Comparative Example.

Power conversion efficiency test: In the atmospheric environment, with an AM1.5G standard light source used as solar simulation light source, a current-voltage characteristic curve of the cell was measured using a four-channel digital source meter (Keithley 2440) under the irradiation of the light source, to obtain the open-circuit voltage Voc, short-circuit current density Jsc, and fill factor FF (Fill Factor) of the cell, and then the power conversion efficiency Eff (Efficiency) of the cell was calculated.

The power conversion efficiency was calculated as follows:

$$Eff = Pout / Popt = Voc \times Jsc \times ( Vmpp \times Jmpp ) / ( Voc \times Jsc ) = Voc \times Jsc \times F F ,$$

where Pout, Popt, Vmpp, and Jmpp were cell operating output power, incident light power, cell voltage at maximum power point, and current at maximum power point, respectively.

Damage to the perovskite absorption layer was characterized by tracking and evaluating the long-term (100 hours) PCE (power conversion efficiency) decay of the cell device. Specifically, the cell was stored in an atmospheric environment without encapsulation, and the PCE changes of the cell were recorded from 0 to 100 hours, with a collection interval of 10 hours. The degree of reduction in PCE after 100 hours compared to the initial PCE was calculated as the damage to the perovskite absorption layer=(initial PCE−PCE at 100-th hour)/initial PCE.

The power conversion efficiency and damage to the perovskite absorption layer of the perovskite solar cells in Examples 1 to 21 and Comparative Example were characterized as shown in Table 3.

TABLE 3

| | | Damage to perovskite |
|---|---|---|
| | Power conversion | absorption layer and loss of |
| | efficiency (%) | efficiency after 100 hours (%) |
| Example 1 | 19.9 | 4.7 |
| Example 2 | 19.7 | 4.9 |
| Example 3 | 19.6 | 5.0 |
| Example 4 | 21.8 | 3.6 |
| Example 5 | 21.5 | 3.7 |
| Example 6 | 21.3 | 3.6 |
| Example 7 | 21.1 | 3.8 |
| Example 8 | 20.7 | 3.8 |
| Example 9 | 20.4 | 4.0 |
| Example 10 | 21.0 | 3.7 |
| Example 11 | 21.2 | 3.8 |
| Example 12 | 20.8 | 3.7 |
| Example 13 | 20.4 | 4.4 |
| Example 14 | 20.3 | 4.5 |
| Example 15 | 20.8 | 3.7 |
| Example 16 | 20.7 | 3.7 |
| Example 17 | 21.1 | 3.5 |
| Example 18 | 20.6 | 3.0 |
| Example 19 | 20.9 | 3.3 |
| Example 20 | 21.2 | 3.4 |
| Example 21 | 21.4 | 6.0 |
| Comparative | 19.5 | 5.2 |
| Example | | |

As shown in Table 3, the power conversion efficiency of the perovskite solar cells in Examples 1 to 21 is significantly higher than that of Comparative Example, indicating that when the perovskite absorption layer, the second charge transport layer, and the second electrode meet both of the relations d=kλ/2n₁ and n₁²=an₂×n₀, the enhanced reflection effect of the second charge transport layer in the perovskite solar cell can be improved, so that part of the light passing through the perovskite absorption layer can be reflected back to the perovskite absorption layer through the second charge transport layer, increasing a quantity of carriers in the perovskite absorption layer, increasing the cell current, and improving the power conversion efficiency of the cell. In addition, the power conversion efficiency of the perovskite solar cells in Examples 4 to 21 is higher than that of Examples 1 to 3, indicating that by doping the second charge transport layer with a radioactive material and making the buffer layer meet the relation n₁²=bn₃×n₀, the power conversion efficiency of the perovskite solar cell can be further improved. Furthermore, the damage to the perovskite absorption layer in the perovskite solar cells of Examples 4 to 20 is lower than that in Example 21, indicating that by arranging a buffer layer between the second charge transport layer and the perovskite absorption layer, the damage to the perovskite absorption layer caused by the radioactive material in the second charge transport layer can be reduced.

In conclusion, it should be noted that the foregoing embodiments are for description of the technical solutions of this application only rather than for limiting this application. Although this application has been described in detail with reference to the foregoing embodiments, persons of ordinary skill in the art should appreciate that they can still make modifications to the technical solutions described in the embodiments or make equivalent replacements to some or all technical features thereof. All such modifications and equivalent replacements do not make the essence of the corresponding technical solutions deviate from the scope of the technical solutions of the embodiments of this application, and shall fall within the scope of claims and specification of this application. In particular, as long as there is no structural conflict, the various technical features mentioned in the embodiments can be combined in any manner. This application is not limited to the specific embodiments disclosed in this specification but includes all technical solutions falling within the scope of the claims.

What is claimed is:

1. A perovskite solar cell, comprising:
a first electrode;
a first charge transport layer, wherein the first charge transport layer is arranged on a side of the first electrode;
a perovskite absorption layer, wherein the perovskite absorption layer is arranged on a side of the first charge transport layer away from the first electrode;
a second charge transport layer, wherein the second charge transport layer is arranged on a side of the perovskite absorption layer away from the first charge transport layer; and
a second electrode, wherein the second electrode is arranged on a side of the second charge transport layer away from the perovskite absorption layer;
wherein the perovskite absorption layer, the second charge transport layer, and the second electrode meet the following relations:
$$d = k λ / 2 {n}_{1} and {n}_{1}^{2} = {an}_{2} \times {n}_{0} ,$$
wherein d represents a thickness of the second charge transport layer in nm;
k is a positive integer;
λ represents a wavelength of a main band of light absorbed by the perovskite absorption layer in nm;
n₀ is a refractive index of the perovskite absorption layer;
n₁ is a refractive index of the second charge transport layer;
n₂ is a refractive index of the second electrode; and
a is a correction factor with a value of 0.5 to 1.5.

2. The perovskite solar cell according to claim 1, wherein the refractive index n₀ of the perovskite absorption layer ranges from 0.5 to 3.

3. The perovskite solar cell according to claim 1, wherein the refractive index n₁ of the second charge transport layer ranges from 0.5 to 3.

4. The perovskite solar cell according to claim 1, wherein the refractive index n₂ of the second electrode ranges from 0.5 to 3.

5. The perovskite solar cell according to claim 1, wherein the second charge transport layer comprises a radioactive material.

6. The perovskite solar cell according to claim 1, wherein based on a total mass of the second charge transport layer, a percentage of the radioactive material in the second charge transport layer does not exceed 30 wt %, and optionally ranges from 3 wt % to 15 wt %.

7. The perovskite solar cell according to claim 1, further comprising a buffer layer, wherein the buffer layer is arranged between the second charge transport layer and the perovskite absorption layer.

8. The perovskite solar cell according to claim 1, wherein a valence band maximum and a conduction band minimum of a material of the buffer layer is at least 2.5 eV apart.

9. The perovskite solar cell according to claim 1, wherein a refractive index n₃ of the buffer layer, the refractive index n₁ of the second charge transport layer, and the refractive index n₂ of the second electrode meet the following relation: n₁²=bn₂×n₃, wherein b is a correction factor with a value of 0.5 to 1.5.

10. The perovskite solar cell according to claim 1, wherein the refractive index n₃ of the buffer layer ranges from 0.5 to 3.

11. The perovskite solar cell according to claim 1, wherein the thickness of the buffer layer does not exceed 10 nm.

12. A method for preparing a perovskite solar cell, comprising:
forming a first charge transport layer on a side of a first electrode;
forming a perovskite absorption layer on a side of the first charge transport layer away from the first electrode;
forming a second charge transport layer on a side of the perovskite absorption layer away from the first charge transport layer; and
forming a second electrode on a side of the second charge transport layer away from the perovskite absorption layer;
wherein the perovskite absorption layer, the second charge transport layer, and the second electrode meet the following relations:
$$d = k λ / 2 {n}_{1}$$
$${n}_{1}^{2} = {an}_{2} \times {n}_{0} ,$$
wherein d represents a thickness of the second charge transport layer in nm;
k is a positive integer;
λ represents a wavelength of a main band of light absorbed by the perovskite absorption layer in nm;
n₀ is a refractive index of the perovskite absorption layer;
n₁ is a refractive index of the second charge transport layer;
n₂ is a refractive index of the second electrode; and
a is a correction factor with a value of 0.5 to 1.5.

13. The method according to claim 12, further comprising: forming a buffer layer between the second charge transport layer and the perovskite absorption layer.

14. An electrical apparatus, comprising the perovskite solar cell according to claim 1.
